(19) United States
(12) Patent Application Publication
(10) Pub. No.: US 2026/0141944 A1
(43) Pub. Date: May 21, 2026

(54) CLOCK DELAY COMPENSATION CIRCUIT AND MEMORY DEVICE INCLUDING THE SAME

(71) Applicant: SAMSUNG ELECTRONICS CO., LTD., Suwon-si (KR)

(72) Inventors: Cheolmin Ahn, Suwon-si (KR); Jaewoo Lee, Suwon-si (KR); Kihan Kim, Suwon-si (KR); Daesik Moon, Suwon-si (KR)

(73) Assignee: SAMSUNG ELECTRONICS CO., LTD., Suwon-si (KR)

(21) Appl. No.: 19/296,321

(22) Filed: Aug. 11, 2025

(30) Foreign Application Priority Data
Nov. 20, 2024 (KR) 10-2024-0166248

(51) Int. Cl. G11C 11/4076; G11C 11/4074; H03K 19/0185

(52) U.S. Cl. CPC G11C 11/4076; G11C 11/4074; H03K 19/018578

(57) ABSTRACT

A memory device includes a memory cell array including a plurality of memory cells, a memory peripheral portion controlling the memory cell array, and an interface including a system clock signal receiver, a data clock signal receiver, a data signal receiver, and a clock delay compensation circuit. The clock delay compensation circuit includes a clock driver including a plurality of cross-coupled latches and a four-phase clock generating circuit. The clock driver generates a second differential clock signal pair using a first differential clock signal pair., The four-phase clock generates a plurality of phase clock signals using the second differential clock signal pair. At least one of the plurality of cross-coupled latches receives an external power supply voltage.

### CROSS-REFERENCE TO RELATED APPLICATION(S)

This application claims priority to Korean Patent Application No. 10-2024-0166248 filed on November 20, 2024 in the Korean Intellectual Property Office, the disclosure of which is incorporated by reference herein in its entirety.

### BACKGROUND

The present disclosure relates to a clock delay compensation circuit and a memory device including the same.

A memory device may operate by exchanging data signals, clock signals, etc. with an external device, such as a host. In order to improve the performance of a system including a memory device, a memory device operating with a plurality of clock signals having different phases has been proposed. In the memory device operating with a plurality of clock signals having different phases, it is necessary to accurately control a phase difference between the plurality of clock signals.

### SUMMARY

Embodiments provide a clock delay compensation circuit capable of accurately controlling a phase difference by compensating for a phase delay of each of a plurality of clock signals by applying an external power supply voltage instead of an internal power supply voltage to a cross-coupled latch connected to a path transmitting a data clock signal, and a memory device including the same.

However, the problems to be solved by the present application are not limited to the problems mentioned above.

According to an aspect of the disclosure, a clock delay compensation circuit including: a clock driver configured to generate a second differential clock signal pair using a first differential clock signal pair, wherein the clock driver includes: a first circuit; a second circuit, each of the first circuit and the second circuit including a plurality of inverters connected in series; and a plurality of cross-coupled latches connected between the first circuit and the second circuit, the first circuit is configured to transmit a first clock signal among the first differential clock signal pair, the second circuit is configured to transmit a second clock signal having a phase opposite to a phase of the first clock signal among the first differential clock signal pair, and a first cross-coupled latch, that is at least one of the plurality of cross-coupled latches, is configured to receive an external power supply voltage.

According to an aspect of the disclosure, a clock delay compensation circuit includes: a four-phase clock generating circuit configured to generate a first phase clock signal, a second phase clock signal having a phase difference of 90 degrees from the first phase clock signal, a third phase clock signal having a phase difference of 180 degrees from the first phase clock signal, and a fourth phase clock signal having a phase difference of 270 degrees from the first phase clock signal using a differential clock signal pair, wherein the four-phase clock generating circuit includes: a first circuit including a first inverter and a second inverter among a plurality of inverters connected in series; a second circuit in including a third inverter and a fourth inverter among the plurality of inverters connected in series; and a plurality of cross-coupled latches, an output terminal of the fourth inverter is connected to an input terminal of the first inverter, wherein an output terminal of the second inverter is connected to an input terminal of the third inverter, one of the plurality of cross-coupled latches connects an output terminal of the first inverter and an output terminal of the third inverter or connects the output terminal of the second inverter and the output terminal of the fourth inverter; and a first cross-coupled latch, being at least one of the plurality of cross-coupled latches, is configured to receive an external power supply voltage.

According to an aspect of the disclosure, a memory device includes: a memory cell array including a plurality of memory cells; a memory peripheral portion configured to control the memory cell array; and an interface including a system clock signal receiver, a data clock signal receiver, a data signal receiver, and a clock delay compensation circuit, wherein the clock delay compensation circuit includes a four-phase clock generating circuit and a clock driver including a plurality of cross-coupled latches, the clock driver is configured to generate a second differential clock signal pair using a first differential clock signal pair, the four-phase clock generating circuit is configured to generate a first phase clock signal, a second phase clock signal having a phase difference of 90 degrees with respect to the first phase clock signal, a third phase clock signal having a phase difference of 180 degrees with respect to the first phase clock signal, and a fourth phase clock signal having a phase difference of 270 degrees with respect to the first phase clock signal using the second differential clock signal pair, and a first cross-coupled latch, being at least one of the plurality of cross-coupled latches, is configured to receive an external power supply voltage.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 is a block diagram illustrating a memory system according to an example embodiment;

FIG. 2 is a circuit diagram illustrating a voltage regulator according to an example embodiment;

FIG. 3 is a block diagram illustrating a transmission path of a data clock signal according to an example embodiment;

FIG. 4 is a circuit diagram illustrating a clock driver according to an example embodiment;

FIGS. 5 and 6 are circuit diagrams illustrating an inverter according to an example embodiment;

FIGS. 7 and 8 are circuit diagrams illustrating a cross-coupled latch according to an example embodiment;

FIG. 9 is a circuit diagram illustrating a four-phase clock generating circuit according to an example embodiment;

FIG. 10 is a circuit diagram illustrating an inverter according to an example embodiment; and

FIGS. 11A, 11B, 11C and 11D are graphs measuring a data clock signal according to an example embodiment.

### DETAILED DESCRIPTION

Hereinafter, example embodiments will be described with reference to the accompanying drawings.

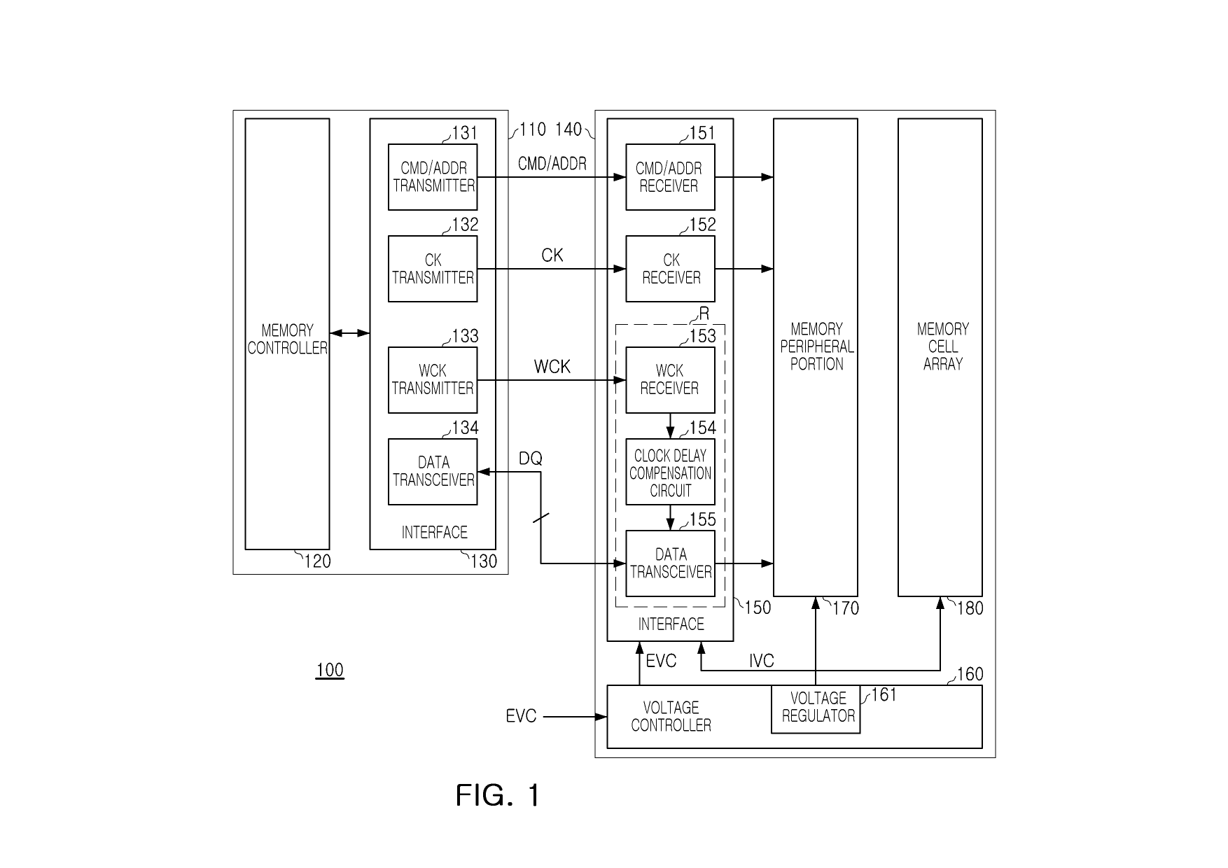

FIG. 1 is a block diagram illustrating a memory system according to an example embodiment.

Referring to FIG. 1, a memory system 100 according to an example embodiment may include a memory device 140 and a host 110 controlling the memory device 140. The host 110 may include a memory controller 120 and a memory controller interface 130. The memory controller interface 130 may include a command/address transmitter 131, a system clock signal transmitter 132, a data clock signal transmitter 133, and a data transceiver 134. The memory controller 120 may control the memory device 140 to write data to the memory device 140 or read data written to the memory device 140. To this end, the memory controller 120 may supply a command/address signal CMD/ADDR, a system clock signal CK, a data clock signal WCK, and a data signal DQ to the memory device 140 through the memory controller interface 130.

The memory device 140 may include a memory cell array 180, a memory peripheral portion 170, a memory device interface 150, and a voltage controller 160. The memory device interface 150 may include a command/address receiver 151, a system clock signal receiver 152, a data clock signal receiver 153, a clock delay compensation circuit 154, and a data transceiver 155. The clock delay compensation circuit 154 may be connected between the data clock signal receiver 153 and the data transceiver 155.

The voltage controller 160 may include a voltage regulator 161 and may receive an external voltage EVC from an external source. The voltage controller 160 may supply the received external voltage EVC to the memory device interface 150. The voltage regulator 161 may generate an internal voltage IVC using the received external voltage EVC. The voltage controller 160 may supply the internal voltage IVC to the memory cell array 180, the memory peripheral portion 170, and the memory device interface 150.

In an example embodiment, the memory device 140 may be a volatile memory device operating as a main memory in an electronic device, and may be, for example, dynamic random access memory (DRAM), such as a low power double data rate (LPDDR). In an example embodiment, the external voltage EVC supplied to the memory device 140 may be a voltage defined in the Joint Electron Device Engineering Council (JEDEC) specification, and the voltage level may be approximately 1.05 V. The memory device 140 may use a data clock signal WCK, a separate signal from the system clock signal CK, to exchange data with the memory controller 120 more promptly. For example, the memory device 140 may receive the data signal DQ transmitted from the host 110 using the data clock signal WCK.

The data transceiver 155 of the memory device 140 may receive the data signal DQ in synchronization with a clock signal generated from the data clock signal WCK. For example, a sampler included in a data transceiver 155 may recover data included in the data signal DQ by sampling the data signal DQ at a rising edge and/or falling edge of a clock signal generated from the data clock signal WCK. Therefore, in order to increase a transfer rate of the data signal DQ received by the memory device 140 and, at the same time, to allow the data transceiver 155 to recover the data included in the data signal DQ without an error, it is necessary to reduce a phase delay of the data clock signal WCK due to a jitter component, etc.

According to an example embodiment, the memory device interface 150 may further include a clock delay compensation circuit 154 which is connected to a transmission path of a data clock signal and compensates for the phase delay of the data clock signal WCK. By pre-compensating for the phase delay that may be included in the clock signal input to the data transceiver 155 with the clock delay compensation circuit 154, the data transceiver 155 may accurately recover data encoded and transmitted as the data signal DQ. For example, the clock delay compensation circuit 154 may reversely compensate for the phase of the data clock signal WCK in a direction opposite to a direction in which the phase of the data clock signal WCK is delayed in a path between the data clock signal receiver 153 and a sampler included in the data transceiver 155.

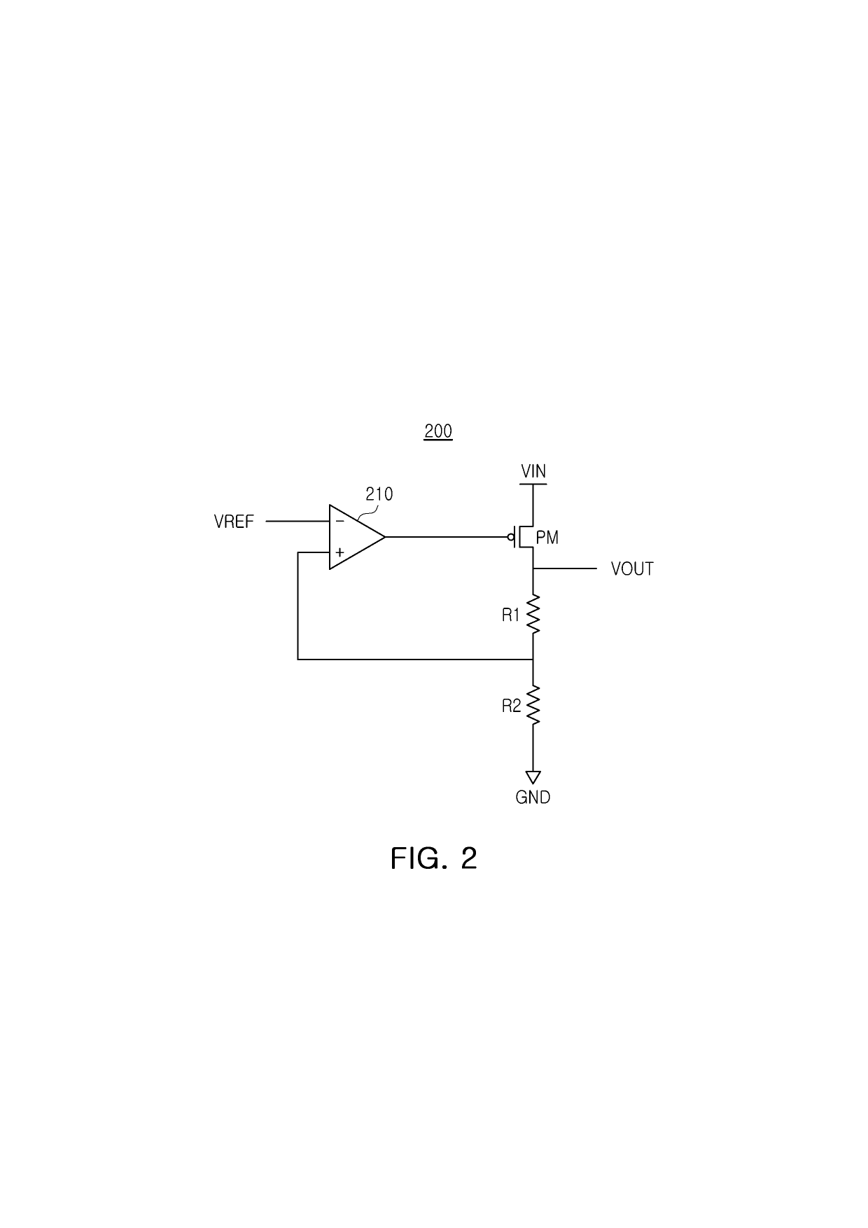

FIG. 2 is a circuit diagram illustrating a voltage regulator 200 according to an example embodiment.

Referring to FIG. 2, the voltage regulator 200 according to an example embodiment may be a low dropout regulator. However, the type of the voltage regulator 200 is not limited thereto. The voltage regulator 200 may include a comparator 210, a transistor PM, a first resistor R1, and a second resistor R2. For example, the transistor PM may be a PMOS, in which case an internal reference voltage VREF may be input to a negative (-) terminal of the comparator 210. Although, in an example embodiment, it is assumed that the transistor is PMOS, the transistor may also be an NMOS, in which case the values input to the two input terminals of the comparator 210 may be interchanged. The transistor PM, the first resistor R1, and the second resistor R2 may be connected in series between an input node to which an input voltage VIN is applied and a reference node to which a reference voltage GND is applied. A connection terminal of the first resistor R1 and the second resistor R2 may be connected to a positive (+) terminal of the comparator 210, so that the voltage regulator 200 may form a feedback structure. An output voltage VOUT may be output to a connection terminal of the transistor PM and the resistor R1.

The voltage regulator 200 may generate an output voltage VOUT having a level required for the operation of the memory device by adjusting the values of the internal reference voltage VREF, the first resistor R1, and the second resistor R2. In addition, the voltage regulator 200 may maintain the level of the output voltage VOUT constant even if a load is additionally connected to an output terminal. In an example embodiment, the low dropout regulator may output a voltage obtained by filtering out noise of the input voltage VIN through the feedback structure as the output voltage VOUT. Therefore, the voltage regulator 200 not only provides the voltage having a required level within the memory device, but also provides the noise-filtered voltage to the memory device at the same time, thereby reducing a phase delay due to noise of a power supply voltage within the memory device.

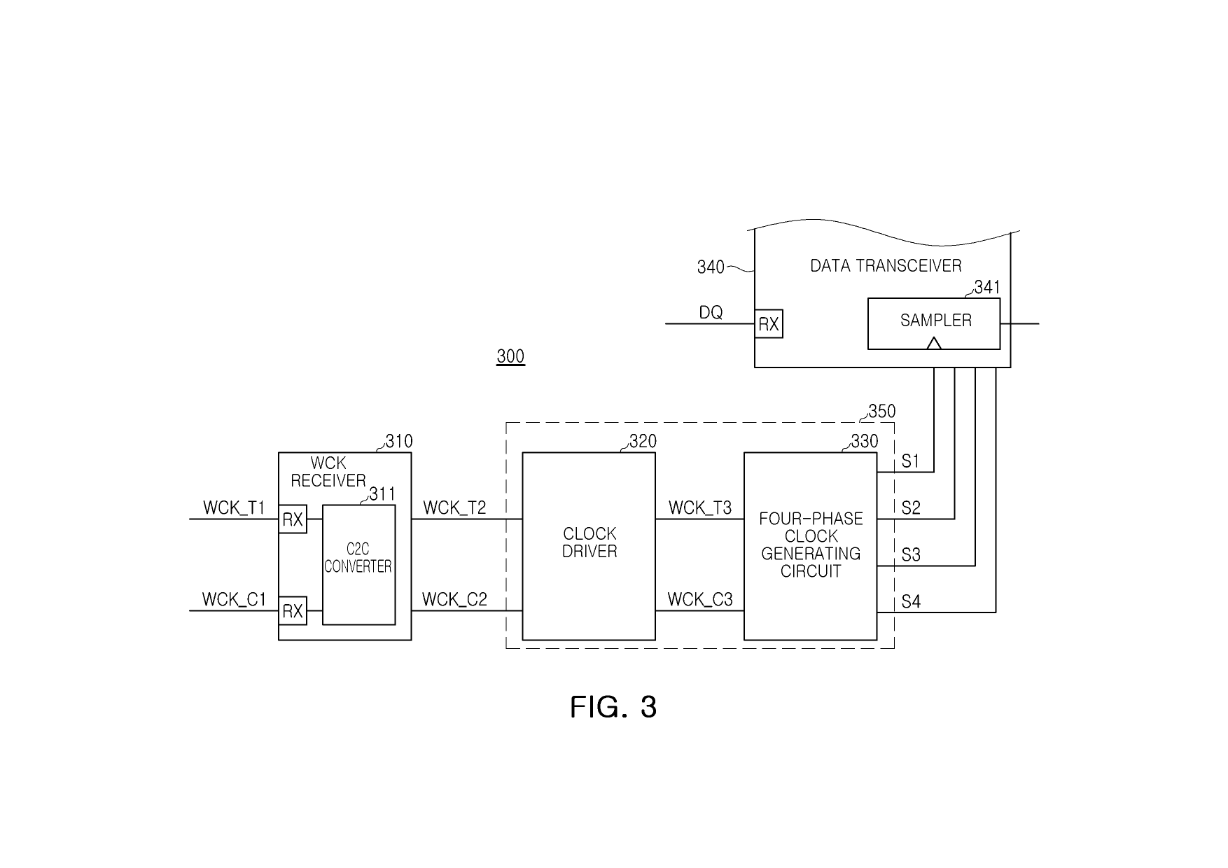

FIG. 3 is a block diagram briefly illustrating a transmission path of a data clock signal according to an example embodiment. FIG. 3 may be a block diagram illustrating region R of FIG. 1 in detail.

Referring to FIG. 3, the transmission path 300 of the data clock signal according to an example embodiment may include a data clock signal receiver 310, a clock delay compensation circuit 350, and a data transceiver 340 and the like. The clock delay compensation circuit 350 may be connected between the data clock signal receiver 310 and the data transceiver 340.

The data clock signal receiver 310 may receive a first differential clock signal pair WCK_T1 and WCK_C1 having opposite phases and a current mode logic (CML) level from the memory controller interface. The data clock signal receiver 310 may include a current mode logic to complementary metal oxide semiconductor (C2C) converter 311, and the C2C converter 311 may receive the first differential clock signal pair WCK_T1 and WCK_C1 and generate a second differential clock signal pair WCK_T2 and WCK_C2 having a complementary metal oxide semiconductor (CMOS) level. In order to perform a high-speed operation, the memory device may receive a CML-level clock signal having a small swing width instead of a CMOS-level clock signal from the memory controller of the host. In general, the CML-level clock signal consumes less power during a high-speed operation than the CMOS-level clock signal and may have low jitter characteristics. Therefore, when the memory device may receive the data clock signal WCK from the outside, the memory device may receive the data clock signal WCK at the CML level and then convert the signal to the CMOS level internally and use the same, thereby rapidly exchanging signals with the memory controller of the host.

The clock delay compensation circuit 350 may include a clock driver 320 and a four-phase clock generating circuit 330. The clock driver 320 may receive the second differential clock signal pair WCK_T2 and WCK_C2 from a data clock signal receiver 310 and may generate a third differential clock signal pair WCK_T3 and WCK_C3 using the same. The four-phase clock generating circuit 330 may receive the third differential clock signal pair WCK_T3 and WCK_C3 from the clock driver 320 and may generate four phase clock signals S1, S2, S3, and S4 having different phases using the same. The four phase clock signals may be a first phase clock signal S1, a second phase clock signal S2 having a phase difference of 90 degrees from the first phase clock signal S1, a third phase clock signal S3 having a phase difference of 180 degrees from the first phase clock signal S1, and a fourth phase clock signal S4 having a phase difference of 270 degrees from the first phase clock signal S1.

The data transceiver 340 may include a data pin RX and a plurality of samplers 341. The phase clock signals S1, S2, S3, and S4 generated by the four-phase clock generating circuit 330 may be input to at least one of the plurality of samplers 341 included in the data transceiver 340.

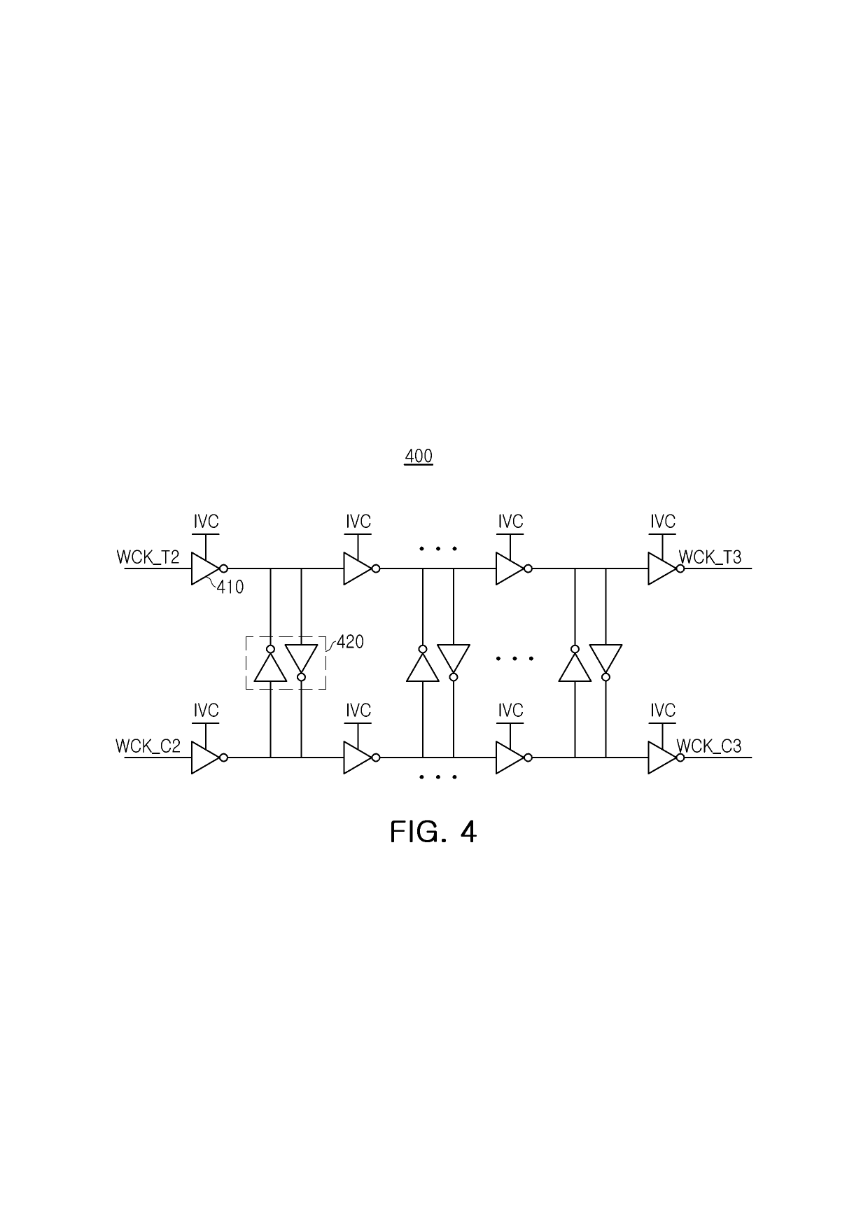

FIG. 4 is a circuit diagram illustrating a clock driver 400 according to an example embodiment.

Referring to FIG. 4, the clock driver 400 according to an example embodiment may include a plurality of inverters 410 and a plurality of cross-coupled latches 420. The clock driver 400 may include a first circuit and a second circuit in which the plurality of inverters 410 are connected in series, and the plurality of cross-coupled latches 420 may be connected between the first circuit and the second circuit. The clock driver 400 may receive the second differential clock signal pair WCK_T2 and WCK_C2 from the data clock receiver and may output the third differential clock signal pair WCK_T3 and WCK_C3. The first circuit may transmit the first clock signal WCK_T2 among the second differential clock signal pair WCK_T2 and WCK_C2, and the second circuit may transmit the second clock signal WCK_C2 having a phase opposite to that of the first clock signal WCK_T2 among the second differential clock signal pair WCK_T2 and WCK_C2.

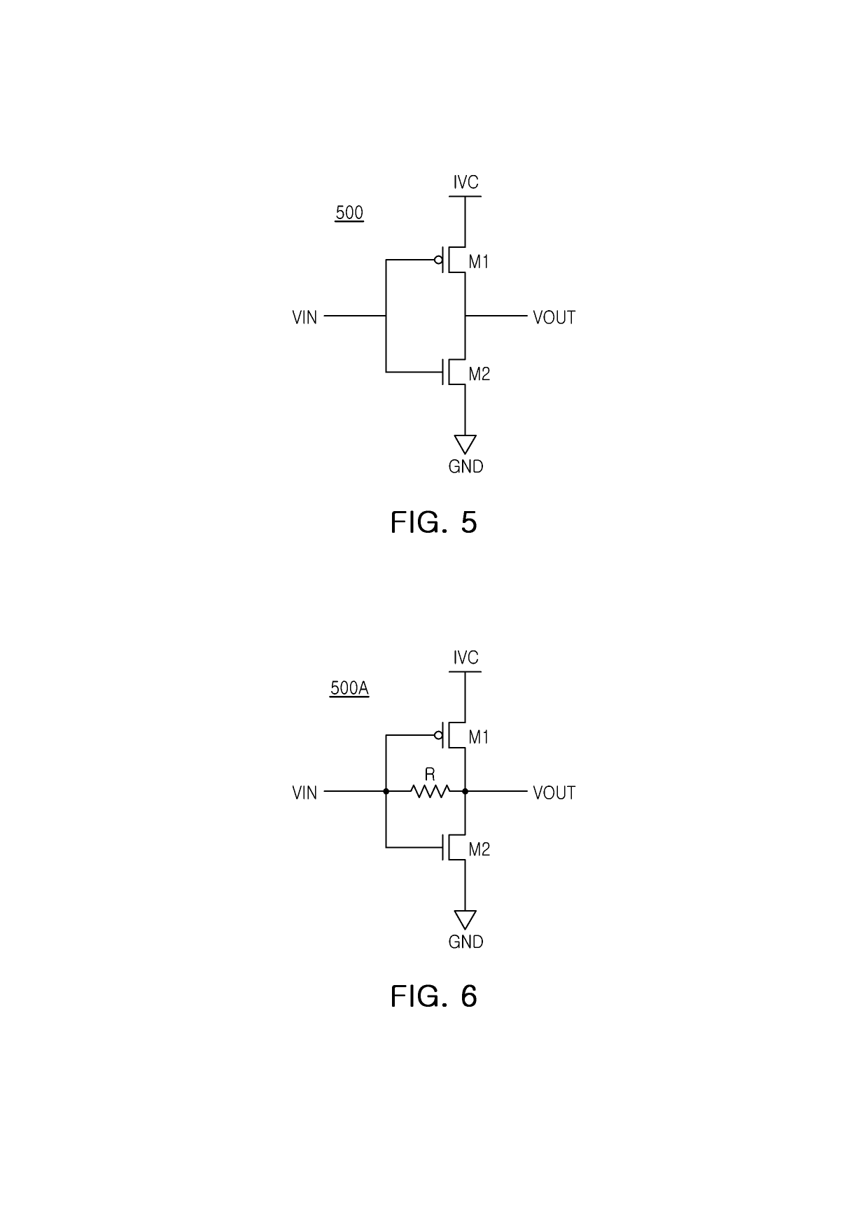

FIGS. 5 and 6 are circuit diagrams illustrating inverters 500 and 500A according to an example embodiment.

Referring to FIG. 5, the inverter 500 according to an example embodiment may include a first transistor M1 and a second transistor M2. The first transistor M1 and the second transistor M2 may be connected in series between a power node to which the internal voltage IVC is applied and a reference node to which a reference voltage GND is applied, and gate terminals of the first transistor M1 and the second transistor M2 may be electrically connected to each other. In an example embodiment, the first transistor M1 and the second transistor M2 may be PMOS and NMOS, respectively. When an input signal VIN is input to the gate terminals of the first transistor M1 and the second transistor M2, an output signal VOUT having a phase opposite to that of to the input signal VIN may be output to a connection terminal of the first transistor M1 and the second transistor M2.

Referring to FIG. 6, the inverter 500A according to an example embodiment may be a resistive feedback inverter 500A including a first transistor M1, a second transistor M2, and a feedback resistor R. The configuration of the first transistor M1 and the second transistor M2 may be similar to that described above with reference to FIG. 5 and may have a structure in which the feedback resistor R is further connected between an input terminal and an output terminal compared to the inverter 500 according to FIG. 5. The feedback resistor R has tolerance to a change in the input signal VIN, thereby reducing noise included in the input signal VIN, so that the resistive feedback inverter 500A may stably maintain the output voltage VOUT.

The structures of the inverters according to an example embodiment are assumed to be the structures of FIG. 5 or FIG. 6, but embodiments are not limited to the structures of the inverters to FIG. 5 or FIG. 6.

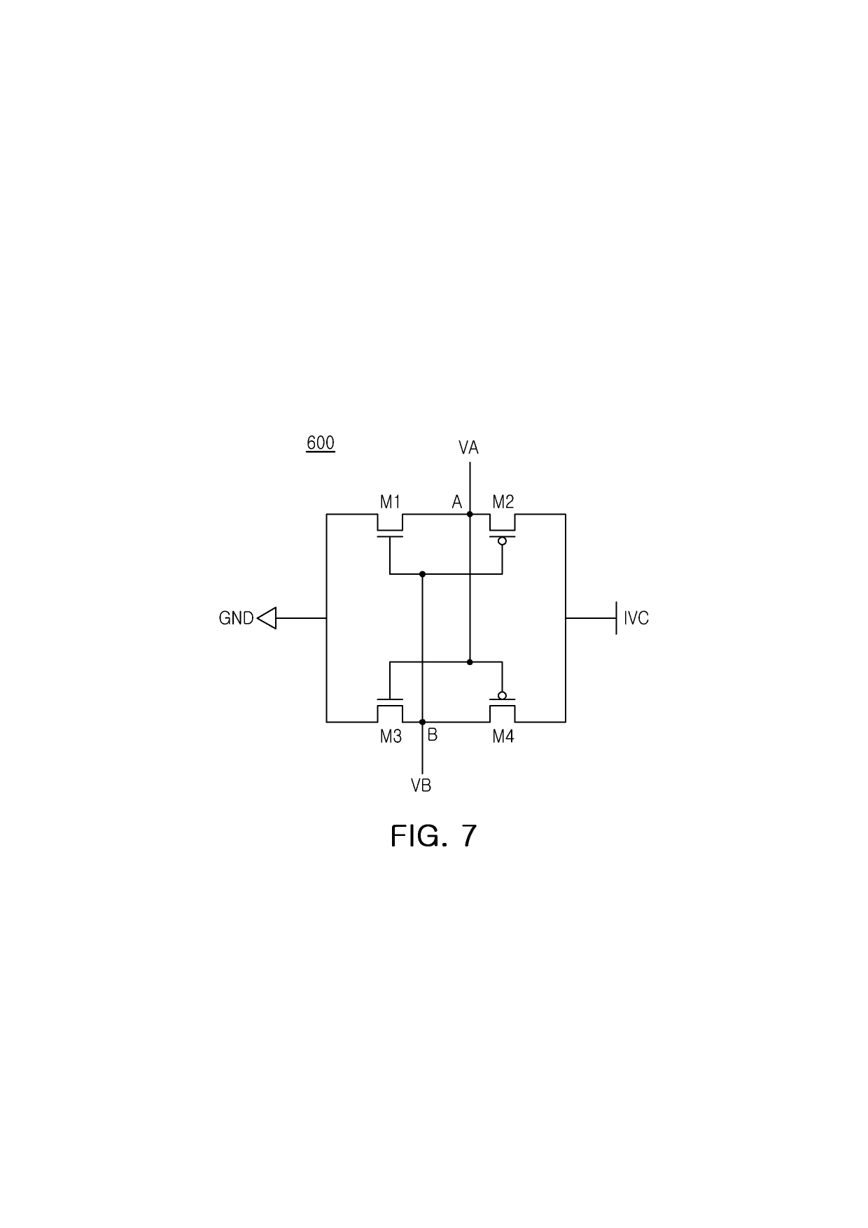

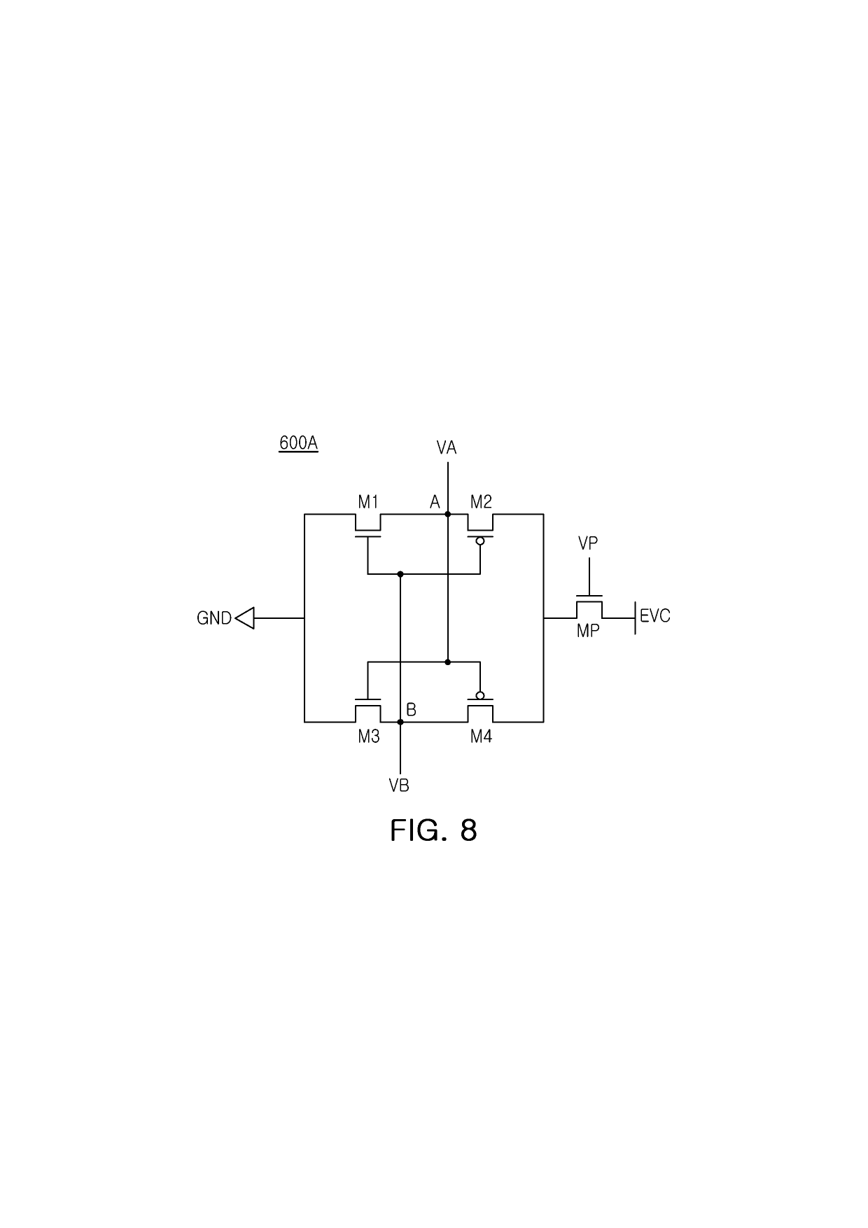

FIGS. 7 and 8 are circuit diagrams illustrating cross-coupled latches 600 and 600A according to an example embodiment.

Referring to FIG. 7, the cross-coupled latch 600 according to an example embodiment has a structure in which two inverters are connected reversely and may include a first transistor M1, a second transistor M2, a third transistor M3, and a fourth transistor M4. In an example embodiment, the first transistor M3 and the third transistor M3 may be NMOS, and the second transistor M2 and the fourth transistor M4 may be PMOS. The cross-coupled latch 600 may have a structure in which the first transistor M1 and the second transistor M2 are connected in series between a power node to which the internal voltage IVC is input and a reference node to which the reference voltage GND is input, and the third transistor M3 and the fourth transistor M4 are connected in series. A connection terminal A of the first transistor M1 and the second transistor M2 may be connected to gate terminals of the third transistor M3 and the fourth transistor M4, which may be connected to the first circuit of the clock driver 400 described above with reference to FIG. 4. A connection terminals B of the third transistor M3 and the fourth transistor M4 may be connected to gate terminals of the first transistor M1 and the second transistor M2, which may be connected to the second circuit of the clock driver 400 described above with reference to FIG. 4.

Referring to FIG. 8, the cross-coupled latch 600A according to an example embodiment may have a structure similar to that of the cross-coupled latch 600 described above with reference to FIG. 7 and may receive the external voltage EVC instead of the internal voltage IVC compared to the cross-coupled latch 600 of FIG. 7 and may further include a power control transistor MP. The power control transistor MP may be connected between the second transistor M2 and the fourth transistor M4 and a power node to which the external voltage EVC is applied.

When a clock driver to which the cross-coupled latch 600A is connected operates, that is, when the data clock signal WCK is transmitted through the clock driver, the power control transistor MP may supply the external voltage EVC to the cross-coupled latch 600A by applying an operating voltage VT to a gate terminal thereof. Conversely, when the clock driver does not operate, the external voltage EVC to the cross-coupled latch 600A may be cut off by applying a cut-off voltage to the gate terminal of the power control transistor MP. With this operation, the power control transistor MP may prevent an error from occurring due to current flowing even when the circuit is not in use due to a level difference when both the internal voltage IVC and the external voltage EVC having different levels are applied within one circuit.

The cross-coupled latches 600 and 600A have a structure in which two inverters are connected reversely to feed back mutual input/output signals. When one output signal VA changes, one inverter reflects the change and outputs the other output signal VB, and the other inverter reflects the changed output signal VB again and outputs the same. In other words, the cross-coupled latches 600 and 600A may have the characteristics of maintaining the state of the two input/output signals VA and VB for a certain period of time, and through this, noise of the two input/output signals VA and VB may be reduced and stabilized.

A phase delay may occur in the process of transmitting signals through various paths within the memory device, and noise in the power supply voltage may be the cause of the phase delay. In order to compensate for the phase delay, the internal voltage IVC from which noise has been filtered by the voltage regulator 200 described above with reference to FIG. 2 may be transmitted to an internal element of the memory device. In addition, the phase delay may be compensated by adding a circuit reducing signal noise and stabilizing the signal, such as the cross-coupled latch 600. However, a signal transmitted along a circuit including an internal element that does not use the internal voltage IVC may still have a phase delay due to noise of the power supply voltage, and the phase delay may not be sufficiently compensated only with the existing cross-coupled latch 600 alone.

The cross-coupled latches 600 and 600A may have different voltage sensitivity, that is, the degree to which the signal flowing to the connected circuit is stabilized, depending on the received voltage. Compared to the cross-coupled latch 600 receiving the internal voltage IVC, the cross-coupled latch 600A receiving the external voltage EVC may have higher voltage sensitivity and may maintain the state of the signal flowing to the connected circuit more strongly and stabilize the same. Therefore, when applying the external voltage EVC to the cross-coupled latch 600A, the signal may be reverse-compensated in the opposite direction of the direction in which the phase of the signal is delayed, compared to when applying the internal voltage IVC to the cross-coupled latch 600A. In this manner, by applying the external voltage EVC instead of the internal voltage IVC to the cross-coupled latch 600A connected to the clock driver, the clock driver may output the data clock signal WCK having a reduced phase delay and low jitter characteristics. Thus, embodiments provide a clock driver using an external voltage for powering cross-coupled latches of the clock driver. The external voltage is supplied from outside the memory device. The internal voltage is obtained by inputting the external voltage to a voltage regulator of the memory device. The cross-coupled latch has a memory aspect which overcomes weak voltage sensitivity of the inverters in series in the clock driver. A similar benefit is obtained in the four-phase clock generation circuit. See FIGS. 2, 3, 4, 8 and 9.

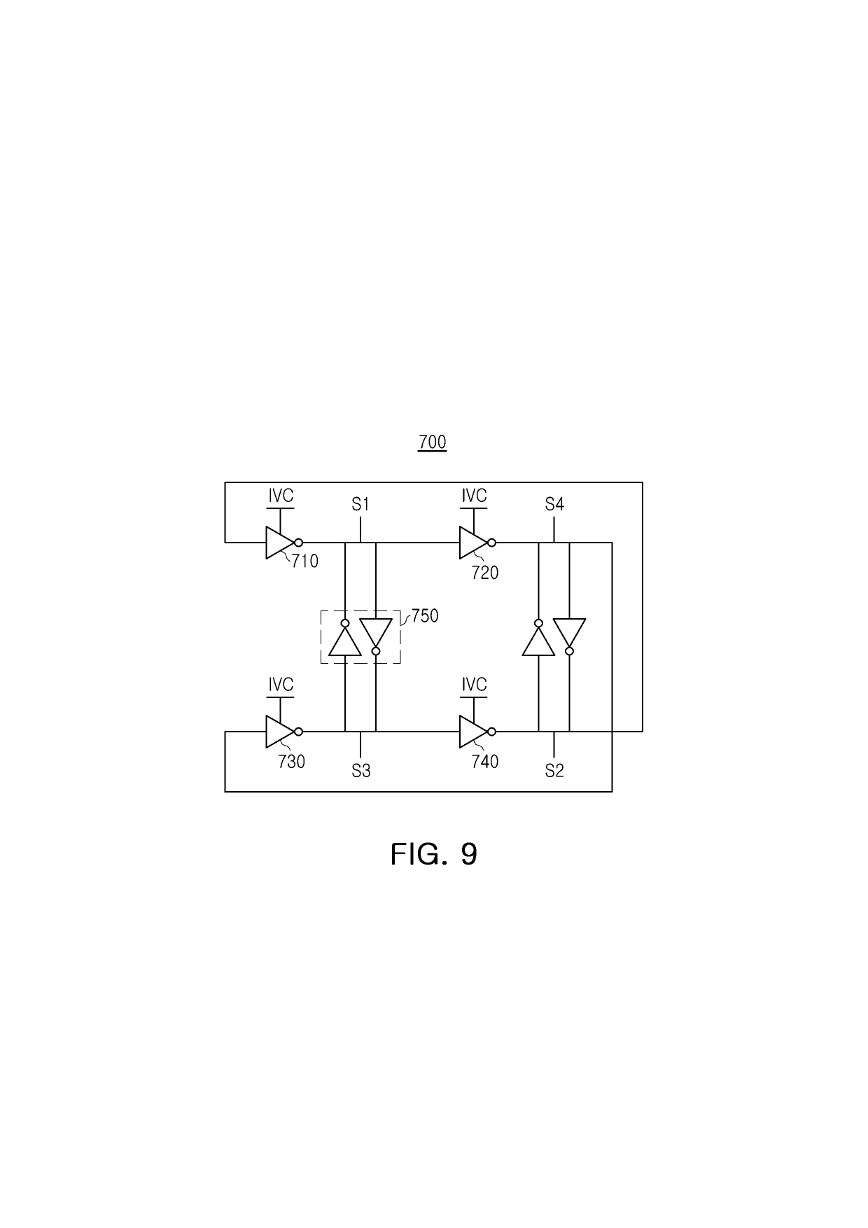

FIG. 9 is a circuit diagram illustrating a four-phase clock generating circuit according to an example embodiment.

Referring to FIG. 9, a four-phase clock generating circuit 700 according to an example embodiment may include a first circuit and a second circuit including a plurality of inverters 710, 720, 730, and 740 and a plurality of cross-coupled latches 750 connecting the first circuit and the second circuit. The first circuit may be a circuit in which a first inverter 710 and a second inverter 720 among the plurality of inverters 710, 720, 730, and 740 are connected in series, and the second circuit may be a circuit in which a third inverter 730 and a fourth inverter 740 among the plurality of inverters 710, 720, 730, and 740 are connected in series. An output terminal of the fourth inverter 740 may be connected to an input terminal of the first inverter 710, and an output terminal of the second inverter 720 may be connected to an output terminal of the third inverter 730.

The four-phase clock generating circuit 700 may output four phase clock signals S1, S2, S3, and S4 having different phases. Among the four phase clock signals S1, S2, S3, and S4, a first phase clock signal S1 may be output from the output terminal of the first inverter 710, the second phase clock signal S2 may be output from the output terminal of the fourth inverter 740, the third phase clock signal S3 may be output from the output terminal of the third inverter 730, and the fourth phase clock signal S4 may be output from the output terminal of the second inverter S2.

One of the plurality of cross-coupled latches 750 may connect the output terminal of the first inverter 710 and the output terminal of the third inverter 730, or may connect the output terminals of the second inverter 720 and the fourth inverter 740. The plurality of cross-coupled latches 750 may be one of the cross-coupled latches 600 described above with reference to FIG. 7 or the cross-coupled latches 600A described above with reference to FIG. 8.

The cross-coupled latches 750 included in the four-phase clock generating circuit 700 may operate similarly to the cross-coupled latch 420 of the clock driver 400 described above with reference to FIG. 4. That is, when the external voltage EVC, instead of the internal voltage IVC, is applied to the cross-coupled latch 750, the signals flowing in the circuits connected to both ends of the cross-coupled latches 750 may be compensated for in the opposite direction of the direction in which the signal is phase-delayed. Accordingly, the four-phase clock generating circuit 700 may output four-phase clock signals S1, S2, S3, and S4 whose phase delays have been compensated for.

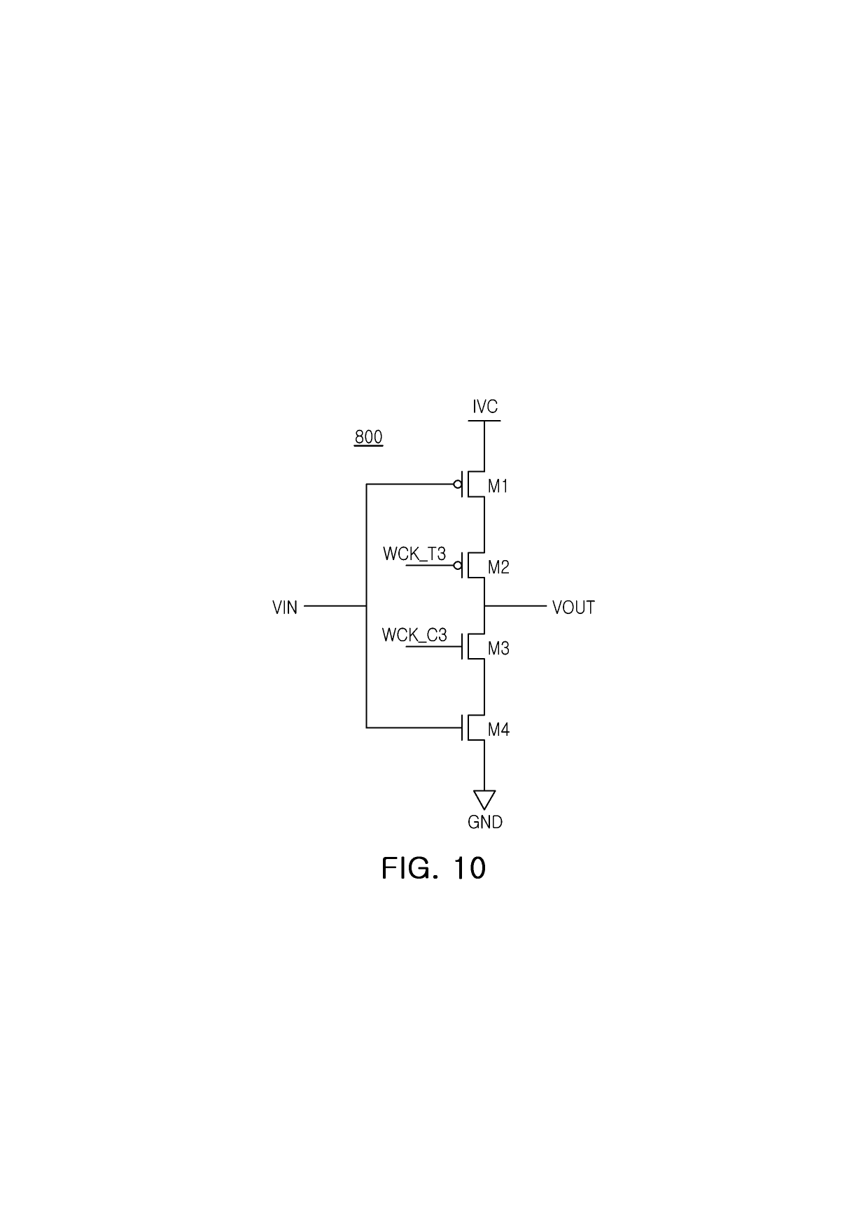

FIG. 10 is a circuit diagram illustrating an inverter according to an example embodiment.

Referring to FIG. 10, an inverter 800 according to an example embodiment may be a circuit diagram of the plurality of inverters 710, 720, 730, and 740 mentioned above with reference to FIG. 9. The inverter 800 may have a structure in which a first transistor M1, a second transistor M2, a third transistor M3, and a fourth transistor M4 are connected in series between a power node to which the internal voltage IVC and a reference node to which a reference voltage GND is applied. The first transistor M1 and the second transistor M2 may be PMOS, and the third transistor M3 and the fourth transistor M4 may be NMOS. The input signal VIN may be applied to the gate terminals of the first transistor M1 and the fourth transistor M4. The first clock signal WCK_T3 among the differential clock signal pair may be input to the gate terminal of the second transistor M2, and the second clock signal WCK_C3 having a phase opposite to that of the first clock signal WCK_T3 among the differential clock signal pair may be input to the gate terminal of the third transistor M3. The output signal VOUT may be output to a connection terminal of the second transistor M2 and the third transistor M3.

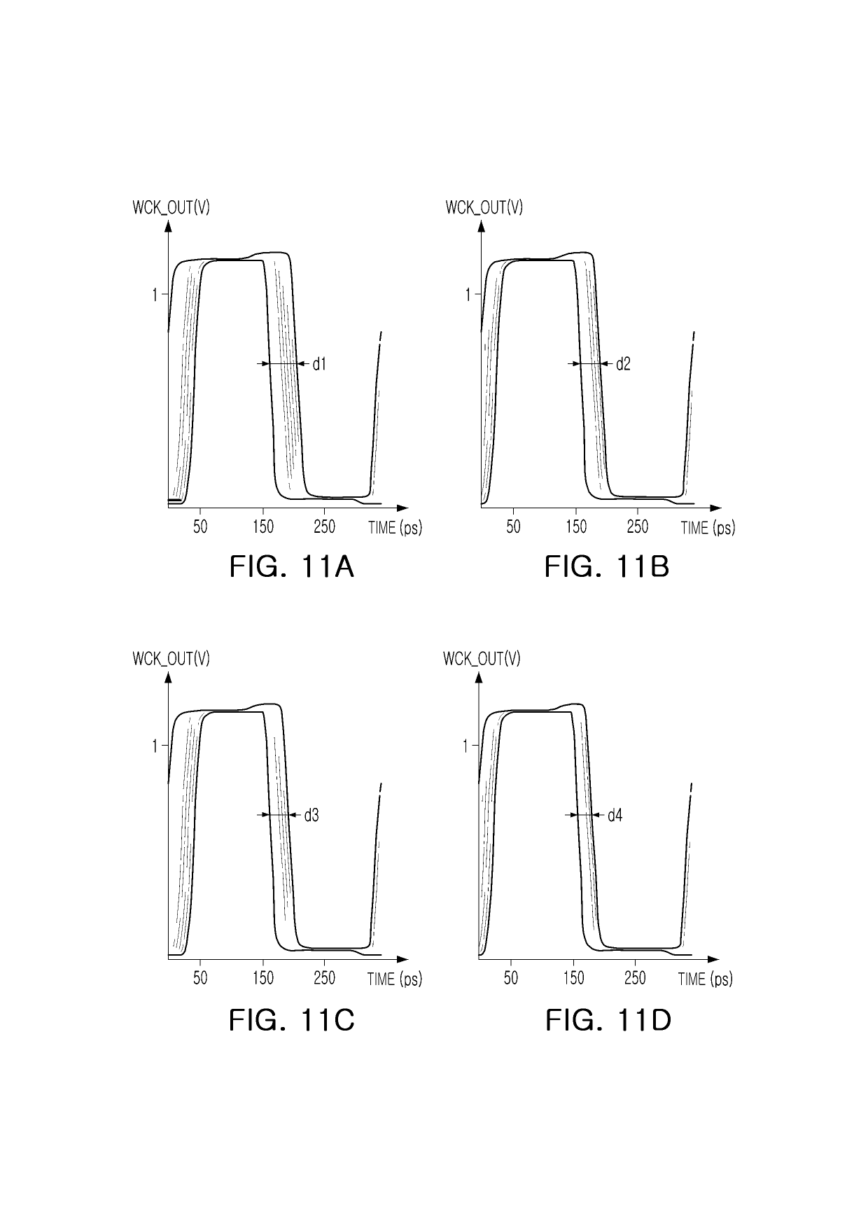

FIGS. 11A, 11B, 11C and 11D are graphs measuring a data clock signal according to an example embodiment.

Referring to FIG. 3, the graphs of FIGS. 11A, 11B, 11C and 11D may be graphs measuring one of the four-phase clock signals S1, S2, S3, and S4 output through the clock delay compensation circuit 350 in the transmission path 300 of the data clock signal according to the embodiment of FIG. 3. The graph above is a graph illustrating the measured signal cut in one-cycle units in an overlapping manner, through which jitter of the measured signal may be checked and compared. FIG. 11A is a graph for a case in which the internal voltage IVC is applied to all cross-coupled latches included in the clock delay compensation circuit 350. FIG. 11B is a graph for a case in which the external voltage EVC is applied to a cross-coupled latch included in the clock driver 320. FIG. 11C is a graph for a case in which the external voltage EVC is applied to a cross-coupled latch included in the four-phase clock generating circuit 330. FIG. 11D is a graph for a case in which the external voltage EVC is applied to both the clock driver 320 and the cross-coupled latches included in the four-phase clock generating circuit 330.

Referring to FIGS. 3, 11A, 11B, 11C and 11D, it can be confirmed that, compared to a case in which only the internal voltage IVC is applied to the cross-coupled latch included in the transmission path 300 of the data clock signal as in FIG. 11A, when the external voltage EVC is applied to the cross-coupled latch included in the clock driver 320 or the four-phase clock generating circuit 330 as in FIGS. 11B and 11C, the jitter of the measured signal was reduced, and when the external voltage EVC is applied to the cross-coupled latch included in both the clock driver 320 and the four-phase clock generating circuit 330 as in FIG. 11D, the jitter of the measured signal was reduced even more. That is, it can be confirmed that, as more cross-coupled latches to which the external voltage EVC is applied are provided in the transmission path 300 of the data clock signal, the degree to which the signal is reversely compensated in the direction opposite to the direction in which the phase of the data clock signal WCK is delayed increases. Therefore, by adjusting the ratio of the cross-coupled latch, which is disposed in the transmission path 300 of the data clock signal, to which the external voltage EVC and the internal voltage IVC is applied, an optimal data clock signal WCK with reduced phase delay may be provided to the sampler, thereby enabling accurate processing of data at a high operation speed.

According to an example embodiment, by adding the clock delay compensation circuit reversely compensating for a signal in a direction opposite to the direction in which the phase of the data clock signal is delayed to the path through which the data clock signal is transmitted, the jitter component included in the data clock signal may be minimized and the phase change of the data clock signal may be reduced. Accordingly, by accurately controlling the phase of the data clock signal input to samplers sampling the data signal, the memory device capable of accurately processing data at a high operating speed may be provided.

While embodiments have been shown and described above, it will be apparent to those skilled in the art that modifications and variations could be made without departing from the scope of the appended claims.

What is claimed is:

1. A clock delay compensation circuit comprising:
a clock driver configured to generate a second differential clock signal pair using a first differential clock signal pair,
wherein the clock driver comprises:
a first circuit;
a second circuit, each of the first circuit and the second circuit comprising a plurality of inverters connected in series; and
a plurality of cross-coupled latches connected between the first circuit and the second circuit,
wherein the first circuit is configured to transmit a first clock signal among the first differential clock signal pair,
wherein the second circuit is configured to transmit a second clock signal having a phase opposite to a phase of the first clock signal among the first differential clock signal pair, and
wherein a first cross-coupled latch, that is at least one of the plurality of cross-coupled latches, is configured to receive an external power supply voltage.

2. The clock delay compensation circuit of claim 1, wherein the first cross-coupled latch comprises a power control transistor.

3. The clock delay compensation circuit of claim 2, wherein the power control transistor is configured to supply the external power supply voltage to the first cross-coupled latch based a first voltage being applied to a gate terminal thereof, and to cut off the external power supply voltage to the first cross-coupled latch based on a second voltage having a level different from that of the first voltage being applied to the gate terminal.

4. The clock delay compensation circuit of claim 1, wherein at least one of the plurality of inverters is a resistive feedback inverter.

5. The clock delay compensation circuit of claim 1, wherein the plurality of inverters are supplied with an internal power supply voltage, and the internal power supply voltage is a voltage generated by a voltage regulator using the external power supply voltage.

6. The clock delay compensation circuit of claim 1, wherein the first differential clock signal pair is a differential clock signal pair having a complementary metal oxide semiconductor (CMOS) level generated by a current mode logic to complementary metal oxide semiconductor (C2C) converter using an external differential clock signal pair having a current mode logic (CML) level.

7. A clock delay compensation circuit comprising:
a four-phase clock generating circuit configured to generate a first phase clock signal, a second phase clock signal having a phase difference of 90 degrees from the first phase clock signal, a third phase clock signal having a phase difference of 180 degrees from the first phase clock signal, and a fourth phase clock signal having a phase difference of 270 degrees from the first phase clock signal using a differential clock signal pair,
wherein the four-phase clock generating circuit comprises:
a first circuit comprising a first inverter and a second inverter among a plurality of inverters connected in series;
a second circuit in comprising a third inverter and a fourth inverter among the plurality of inverters connected in series; and
a plurality of cross-coupled latches,
wherein an output terminal of the fourth inverter is connected to an input terminal of the first inverter,
wherein an output terminal of the second inverter is connected to an input terminal of the third inverter,
wherein one of the plurality of cross-coupled latches connects an output terminal of the first inverter and an output terminal of the third inverter or connects the output terminal of the second inverter and the output terminal of the fourth inverter; and
wherein a first cross-coupled latch, being at least one of the plurality of cross-coupled latches, is configured to receive an external power supply voltage.

8. The clock delay compensation circuit of claim 7, wherein the first cross-coupled latch comprises a power control transistor.

9. The clock delay compensation circuit of claim 8, wherein the power control transistor is configured to supply the external power supply voltage to the first cross-coupled latch based on a first voltage being applied to a gate terminal thereof, and to cut off the external power supply voltage to the first cross-coupled latch based on a second voltage having a level different from that of the first voltage being applied to the gate terminal.

10. The clock delay compensation circuit of claim 7, wherein each the plurality of inverters comprises a first transistor, a second transistor, a third transistor, and a fourth transistor connected in series between a power node and a reference node,
wherein an input signal is input to gate terminals of the first transistor and the fourth transistor,
wherein a first clock signal among the differential clock signal pair is input to a gate terminal of the second transistor, and
wherein a second clock signal having a phase opposite to that of the first clock signal among the differential clock signal pair is input to a gate terminal of the third transistor.

11. The clock delay compensation circuit of claim 7, wherein the plurality of inverters are configured to be supplied with an internal power supply voltage, and the internal power supply voltage is a voltage generated by a voltage regulator using the external power supply voltage.

12. A memory device comprising:
a memory cell array comprising a plurality of memory cells;
a memory peripheral portion configured to control the memory cell array; and
an interface comprising a system clock signal receiver, a data clock signal receiver, a data signal receiver, and a clock delay compensation circuit,
wherein the clock delay compensation circuit comprises a four-phase clock generating circuit and a clock driver comprising a plurality of cross-coupled latches,
wherein the clock driver is configured to generate a second differential clock signal pair using a first differential clock signal pair,
wherein the four-phase clock generating circuit is configured to generate a first phase clock signal, a second phase clock signal having a phase difference of 90 degrees with respect to the first phase clock signal, a third phase clock signal having a phase difference of 180 degrees with respect to the first phase clock signal, and a fourth phase clock signal having a phase difference of 270 degrees with respect to the first phase clock signal using the second differential clock signal pair, and
wherein a first cross-coupled latch, being at least one of the plurality of cross-coupled latches, is configured to receive an external power supply voltage.

13. The memory device of claim 12, wherein the first cross-coupled latch comprises a power control transistor.

14. The memory device of claim 13, wherein the power control transistor is configured to supply the external power supply voltage to the first cross-coupled latch based on a first voltage being applied to a gate terminal thereof, and to cut off the external power supply voltage to the first cross-coupled latch based on a second voltage having a level different from that of the first voltage being applied to the gate terminal.

15. The memory device of claim 12, wherein the clock driver comprises a first plurality of inverters, and the four-phase clock generating circuit comprises a second plurality of inverters.

16. The memory device of claim 15, wherein at least one of the first plurality of inverters of the clock driver is a resistive feedback inverter.

17. The memory device of claim 15, whereinthe second plurality of inverters of the four-phase clock generating circuit comprises a first transistor, a second transistor, a third transistor, and a fourth transistor connected in series between a power node and a reference node,
wherein an input signal is input to gate terminals of the first transistor and the fourth transistor,
wherein a first clock signal among the second differential clock signal pair is input to a gate terminal of the second transistor, and
wherein a second clock signal having a phase opposite to that of the first clock signal among the second differential clock signal pair is input to a gate terminal of the third transistor.

18. The memory device of claim 12, further comprising a voltage regulator configured to generate an internal power supply voltage using the external power supply voltage, wherein the internal power supply voltage is a filtered voltage.

19. The memory device of claim 18, wherein the voltage regulator is a low dropout regulator.

20. The memory device of claim 12, wherein the system clock signal receiver comprises a current mode logic to complementary metal oxide semiconductor (C2C) converter,
wherein an external differential clock signal pair has a current mode logic level, and
wherein the first differential clock signal pair is a differential clock signal pair having a complementary metal oxide semiconductor level generated by the C2C converter using the external differential clock signal pair.
